(19) United States
(12) Patent Application Publication
(10) Pub. No.: US 2008/0123299 A1
(43) Pub. Date: May 29, 2008

(54) Circuit Device and Manufacturing Method of the Same

(76) Inventors: Sadamichi Takakusaki, Gunma (JP); Yusuke Igarashi, Gunma (JP); Motoichi Nezu, Gunma (JP); Takaya Kusabe, Gunma (JP)

Correspondence Address: FISH & RICHARDSON P.C., P.O. BOX 1022, MINNEAPOLIS, MN, 55440-1022, US

(21) Appl. No.: 10/599,302

(22) PCT Filed: Mar. 24, 2005
(86) PCT No.: PCT/JP05/06232

§ 371 Date: Sep. 25, 2006

(30) Foreign Application Priority Data
Mar. 29, 2004 (JP) 2004-094684

(51) Int. Cl. H05K 7/20; H05K 3/30

(52) U.S. Cl. 361/719; 29/832

(57) ABSTRACT

A circuit device exhibiting excellent heat radiation properties and a manufacturing method thereof are hereby provided. A circuit device comprises a circuit board, an insulating layer formed on the circuit board, a conductive pattern formed on the insulating layer, a circuit element electrically connected to the conductive pattern, wherein a protrusion partially extending and being buried in the insulating layer is provided on the circuit board. Accordingly, heat generated inside the device can be efficiently discharged to the exterior via the protrusion.

Priority is claimed to Japanese Patent Application Number JP2004-094684 filed on Mar. 29, 2004, the disclosure of which is incorporated herein by reference in its entirety.

### BACKGROUND OF THE INVENTION

1. Field of the Invention

This invention relates to a circuit device and a manufacturing method thereof, more particularly to a circuit device having improved heat radiation properties and a manufacturing method thereof.

2. Description of the Related Art

Configuration of a conventional hybrid integrated circuit device is described with reference to FIG. 10, where FIG. 10A is a perspective view of a hybrid integrated circuit device 100 and FIG. 10B is a sectional view taken along line X-X′ shown in FIG. 10A.

The conventional hybrid integrated circuit device 100 comprises a rectangular substrate 106, an insulating layer 107 provided on the substrate 106, conductive patterns 108 formed on the insulating layer 107, a circuit element 104 fixed on a conductive pattern 108, fine metal wires 105 electrically connecting the circuit element 104 with the conductive patterns 108, and leads 101 electrically connected with the conductive patterns 108. The above-described hybrid integrated circuit device 100 is entirely sealed by a sealing resin 102.

In the above-described hybrid integrated circuit device 100, the insulating layer 107 having electrical circuitry formed thereon thermally separates the circuit element 104 from the substrate 106 thus causing problems with radiation of heat discharged from the circuit element 104. It is possible to improve heat radiation by providing a thinner insulating layer 107, however, the insulating layer must have a thickness equal to or above a predetermined value in order to ensure withstand voltage. Concretely, the insulating layer 107 must be several hundred μm thick. An inorganic filler is filled in order to improve thermal resistance of the insulating layer 107 itself, however, there are limits to heat radiation via insulating layer 107.

### SUMMARY OF THE INVENTION

The preferred embodiments of the present invention have been developed in view of the above-described and/or other problems and a main aspect thereof is to provide a circuit device having excellent heat radiation properties while ensuring predetermined withstand voltage properties, and a manufacturing method thereof.

A circuit device of some preferred embodiments of the present invention includes a circuit board, an insulating layer formed on the circuit board, conductive patterns formed on the surface of the insulating layer, a circuit element electrically connected to the conductive patterns, wherein a protrusion partially extending and being buried in the insulating layer is provided on the surface of the circuit board.

Furthermore, the protrusion and the conductive patterns are preferably put in direct contact.

Furthermore, the insulating layer is preferably provided between the protrusion and the conductive pattern.

Furthermore, the protrusion is preferably provided under the conductive pattern having a circuit element disposed thereon, at a corresponding location in the surface of the circuit board.

Furthermore, the circuit board is preferably formed of a metal mainly comprising copper.

The protrusion has a column-like shape.

With a circuit device of some embodiments, preferably, a semiconductor element having no terminals on a back surface thereof is employed as a circuit element, a protrusion is provided on a surface of a circuit board at a location corresponding to a lower side of a conductive pattern having a semiconductor element fixed thereon, so that the conductive pattern and the protrusion are in direct contact.

In a circuit device manufacturing method according to some preferred embodiments, forming electrical circuitry comprising a conductive pattern and a circuit element on a circuit board via an insulating layer includes providing on a surface of the circuit board a protrusion extending partially and being buried in the insulating layer.

Furthermore, a circuit device manufacturing method according to some embodiments includes providing a protrusion extending partially on a surface of an circuit board, attaching a conductive foil on the circuit board via an insulating layer covering the circuit board so as to bury the protrusion, forming a conductive pattern by patterning the conductive foil and electrically connecting the conductive pattern with the circuit element.

Furthermore, the protrusion is preferably formed by etching.

In a circuit device manufacturing method according to some embodiments, a plurality of protrusions are provided in a location corresponding to one conductive pattern.

Furthermore, in a circuit device manufacturing method according to some embodiments, an upper surface of the protrusion is formed to be planar and an insulating layer is interposed between the protrusion and the conductive pattern.

Furthermore, sidewalls of the protrusion are formed to have a curved surface.

According to this invention, the distance between the circuit board and the conductive pattern having an insulating layer formed thereon can be topically reduced by burying the protrusion provided on the circuit board in an insulating layer. The insulating layer can reduce thermal resistance thus enabling improvement of heat radiation properties. Moreover, by contacting the protrusion with the back surface of the conductive pattern, heat radiation effects can significantly be improved. It is also possible to approximate the conductive pattern and the protrusion while ensuring insulation therebetween by interposing a resin forming an insulating layer. The protrusion has a column-like shape so as to facilitate burying of the protrusion in the insulating layer.

### BRIEF DESCRIPTION OF THE DRAWINGS

FIG. 1A is a perspective view and FIG. 1B is a cross-sectional view showing a hybrid integrated circuit device according to embodiments of the present invention.

FIG. 2 is a perspective view of a hybrid integrated circuit device according to the embodiments of the present invention.

FIG. 3A to FIG. 3C are cross-sectional views showing a hybrid integrated circuit device according to the embodiments of the present invention.

FIG. 4A to FIG. 4C are cross-sectional views illustrating a hybrid integrated circuit device according to the embodiments of the present invention.

FIG. 5A to FIG. 5F are cross-sectional views showing a manufacturing method of a hybrid integrated circuit device according to the embodiments of the present invention.

FIG. 6A to FIG. 6F are cross-sectional views illustrating a manufacturing method of a hybrid integrated circuit device according to the embodiments of the present invention.

FIG. 7A to FIG. 7F are cross-sectional views showing a manufacturing method of a hybrid integrated circuit device according to the embodiments of the present invention.

FIG. 8A and FIG. 8B are cross-sectional views showing a manufacturing method of a hybrid integrated circuit device according to the embodiments of the present invention.

FIG. 9 is a cross-sectional view illustrating a manufacturing method of a hybrid integrated circuit device according to the embodiments of the present invention.

FIG. 10A is a perspective view and FIG. 10B is a sectional view of a conventional hybrid integrated circuit device.

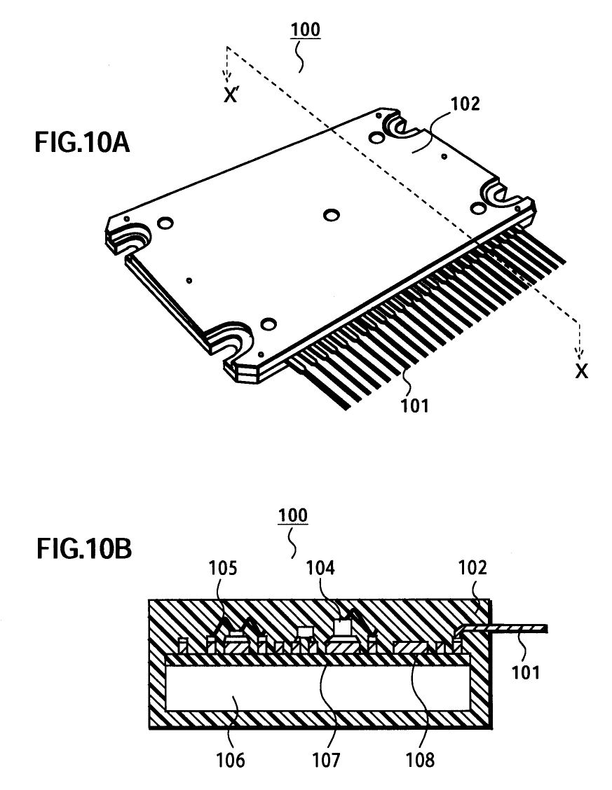

### DETAILED DESCRIPTION OF THE EMBODIMENTS

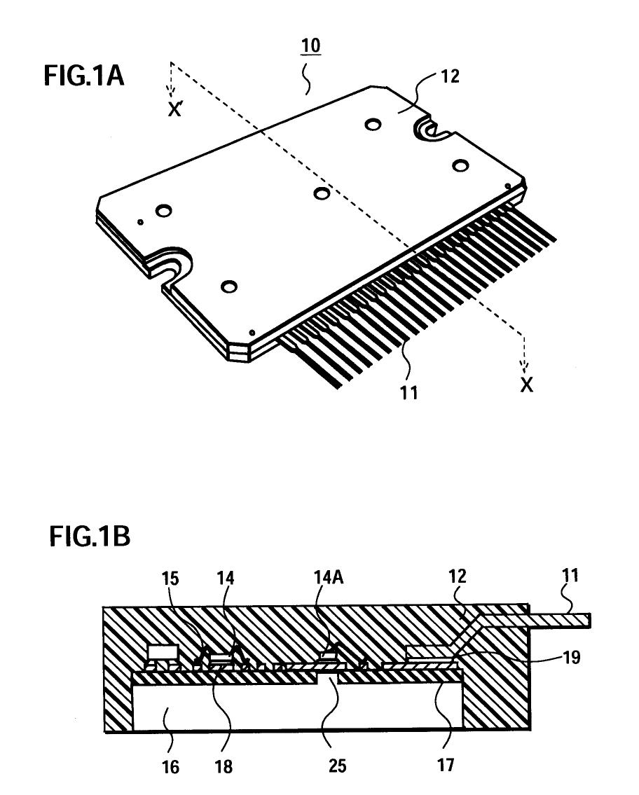

Structure of a hybrid integrated circuit device 10 according to an embodiment of the present invention is described with reference to FIG. 1, where FIG. 1A is a perspective view of the hybrid integrated circuit device 10 and FIG. 1B is a cross-sectional view taken along the line X-X′ of FIG. 1A.

A circuit board 16 is employed which is preferably a board comprising metal or ceramic, etc. and having heat radiation properties. Al, Cu or Fe can be employed as material for the circuit board 16 of metal, or Al₂O₃, AlN for the ceramic circuit board 16. Other materials exhibiting excellent mechanical strength and heat radiation properties can be employed as materials for the circuit board 16. For example, when a circuit board of Al is used as the circuit board 16, there are two methods for providing insulation between the circuit board 16 and a conductive patterns 18 formed on a surface thereof. One method is to carry out an alumite treatment of the surface of the Al circuit board. A second method is to form an insulating layer 17 on the Al circuit board and further form the conductive pattern 18 on the insulating layer. In some preferred embodiments of the present invention, the metal circuit board 16 having Cu as a main material is preferably employed. Since Cu is a material having excellent heat conductance, heat radiation properties of the overall device can be improved. Here, when the Cu circuit board 16 is used, the insulating layer 17 becomes an indispensable constituent feature.

A protrusion 25 is a portion partially protruding upward on the surface of the circuit board 16 and thus being buried in the insulating layer 17. The distance between an upper surface of the protrusion 25 and a back surface of the conductive pattern 18 is shorter than the distance between a surface of the circuit board 16 at other locations and the back surface of the conductive pattern 18. Accordingly, the thermal resistance by the insulating layer 17 at the location where the protrusion 25 is formed is low and heat radiation via circuit board 16 can be carried out positively. The upper edge of the protrusion 25 may contact the back surface of the conductive pattern 18, and it doesn't have to contact there. The shape, etc. of the protrusion 25 is to be further described in more detail. The protrusion 25 is preferably provided in a region corresponding to a lower part of a heat-generating semiconductor element 14A. With this structure, heat generated from the semiconductor element 14A is discharged to the outside.

A circuit element 14 is fixed on the conductive pattern 18 so that a predetermined electrical circuit is formed by the circuit element 14 and the conductive pattern 18. Active elements such as transistors or diodes, etc. or passive elements such as capacitors or resistors, etc. can be employed as the circuit element 14. Also, elements with a high calorific value such as power semiconductor elements, etc. may be fixed to the circuit board 16 via a heat sink formed of metal. Here, active elements, etc. mounted face-up are electrically connected with the conductive pattern 18 via fine metal wires 15.

LSI chips, capacitors, resistors, etc. can be used as the circuit element 14. Adhesives used in an LSI chip are differentiated according to the back surface of the Si chip which may be GND or floating. In case of GND, the rear surface of the circuit element 14 is fixed by means of brazing material or conductive paste and connection with the bonding pad and the circuit element 14 is made by use of fine metal wires, in case of face-up mounting, or brazing material, etc. in case of face-down mounting. Furthermore, power transistors such as power MOS, GTBT, IGBT, thyristors capable of controlling a large current can be used as the semiconductor element 14A. Power ICs can also be employed. With high-performance and compact chips nowadays, the amount of heat generated is increasing; the CPU controlling a computer is just an example of such a chip.

The conductive pattern 18 can be formed of a metal such as Cu and is insulated from the circuit board 16. A pad formed of the conductive pattern 18 is formed in an area where a lead 11 is provided. Here, an example is described where the lead 11 is provided at one side of the circuit board 16, but the lead may be provided at least at one side of the circuit board 16. The conductive pattern 18 is attached to the circuit board 16 using the insulating layer 17 as an adhesive.

The insulating layer 17 is formed on the entire circuit board 16 and has the function of attaching the back surface of the conductive pattern 18 to the surface of the circuit board 16. The insulating layer 17 comprises a resin filled with an inorganic filler such as alumina and has excellent heat conductance. The thickness between the lower end of the conductive pattern 18 and the surface of the circuit board 16 varies with withstand voltage preferably in the range of from about 50 μm to several hundreds μm or more.

The lead 11 is fixed to the pad provided in the periphery of the circuit board 16 and carries out, for instance signal input/output with the exterior. Here, a plurality of the leads 11 is provided on one side of the circuit board 16. The leads 11 and the pads are attached via a conductive adhesive such as solder etc.

A sealing resin 12 is formed by transfer mold using a thermo-setting resin or by injection mold using thermoplastic resin. Here, the sealing resin 12 is formed to seal the circuit board 16 and the electric circuitry formed on the circuit board 16 while leaving the back surface of the circuit board 16 exposed from the sealing resin 12. It is also possible to apply other sealing methods, besides mold sealing, to the hybrid integrated circuit device according to this embodiment. Such other sealing methods include sealing by resin potting, sealing by a case member or other commonly known method. In FIG. 1B, the back surface of the circuit board 16 is exposed to exterior from the sealing resin 12 in order to optimally discharge heat generated from the circuit element 14 mounted on the circuit board 16. In order to improve moisture resistance of the entire device, the entire assembly, including the back surface of the circuit board 16 can be sealed by the sealing resin 12.

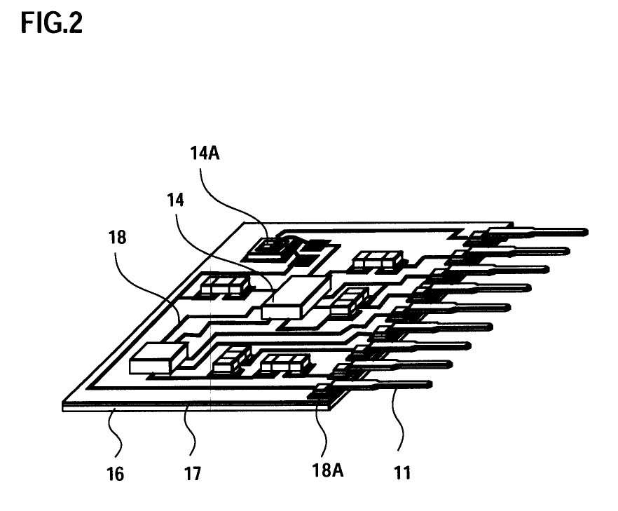

FIG. 2 which is a perspective view shows an example of an embodiment where the conductive patterns 18 are formed on the circuit board 16. In this figure, the resin sealing the entire assembly is omitted.

In FIG. 2, the conductive patterns 18 form the bonding pads having the circuit element 14 mounted thereon, pads 18C fixing the leads 11, wires interconnecting the pads, etc. In the present embodiment, the protrusion 25 can be formed in the circuit board 16 in a region corresponding to a lower part of the semiconductor element 14A. Also, in case heat radiation of the other circuit elements 14 becomes problematic, the protrusion 25 can be formed on the surface of the circuit board 16 in a region corresponding to a lower part of that respective element.

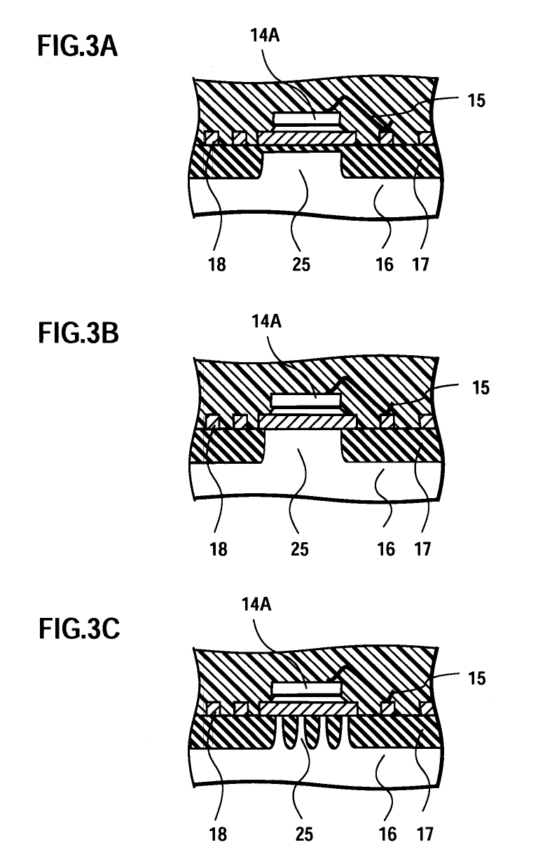

A more detailed description of the location of the protrusion 25 is next given with reference to FIGS. 3A to FIG. 3C illustrating different embodiments of the protrusion 25.

In FIG. 3A, the protrusion 25 is formed on the surface of the circuit board 16 in a region corresponding to a lower part of the semiconductor element 14A. The upper end of the protrusion 25 and the back surface of the conductive pattern 18 are spaced. A resin forming the insulating layer 17 is interposed between the protrusion 25 and the conductive pattern 18 so that the conductive pattern 18 and the circuit board 16 do not communicate electrically. With this structure, it is possible to ensure insulation between the circuit board 16 and the conductive pattern 18 having the semiconductor element 14A mounted thereon, while discharging heat generated from the semiconductor element 14A to exterior via protrusion 25. Here, an element provided with electrodes on a back surface thereof can be employed as the semiconductor element 14A. Concretely, a power transistor provided with drain electrodes on a back surface thereof can be employed as the semiconductor element 14A. Here, by planarizing the upper surface of the protrusion 25, contact between the protrusion 25 and the conductive pattern 18 can be avoided.

The distance range between the upper end of the protrusion 25 and the back surface of the conductive pattern 18 is preferably such that a withstand voltage can be obtained. By making this distance larger than the filler included in the insulating layer 17, filler can be provided between the protrusion 25 and the conductive pattern 18 to improve heat radiation.

In FIG. 3B, the uppermost part of the protrusion 25 contacts the back surface of the conductive pattern 18 having the semiconductor element 14A mounted thereon so that heat generated from the semiconductor element 14A can be discharged to the exterior. With such a structure, semiconductor elements having no electrodes on a back surface thereof can be employed as the semiconductor element 14A. It is also possible to connect the circuit board 16 to a ground potential via the protrusion 25. Also, with the structure shown in FIG. 3B, by attaching the semiconductor element 14A via an insulating adhesive, the semiconductor element 14A and the circuit board can be insulated.

In FIG. 3C, a plurality of column-like the protrusions 25 are formed and upper ends thereof are in direct contact with the back surface of the conductive pattern 18. Here, each protrusion 25 has a conical form of which upper end is cut. This shape can be obtained by a etching process using an etchant. Moreover, a plurality of the protrusions 25 are formed under one conductive pattern 18. Accordingly, forming the column-like protrusions 25 can facilitate burying the protrusions into the insulating layer. Also, contact between the upper part of the protrusion 25 and the conductive pattern 18 is assured.

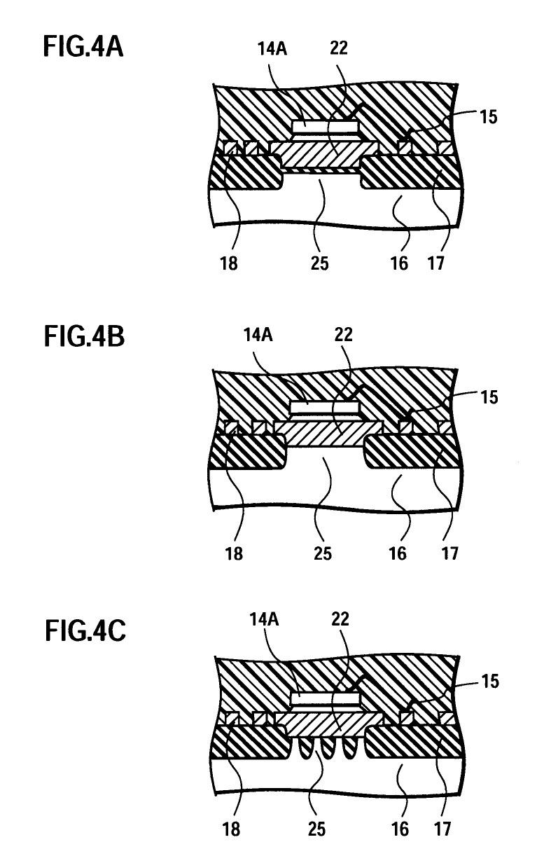

The location where the protrusion 25 is provided is now described in detail with reference to FIG. 4A to FIG. 4C showing the relational configuration between the conductive pattern 18 and each respective embodiment of the protrusion 25. Here, a convex portion 22 is provided on a back surface of the conductive pattern 18 mounting the semiconductor element 14A thereon.

In FIG. 4A, the convex portion 22 is formed in the conductive pattern 18 mounting the semiconductor element 14A thereon, extends downwardly and is buried in the insulating layer 17. The protrusion 25 is formed on a surface of the circuit board 16 at a location corresponding to the convex portion 22. By thus approximating the convex portion 22 and the protrusion 25, heat generated from the semiconductor element 14A can be efficiently discharged to exterior.

Advantages of a configuration where the conductive pattern 18 is partially buried in the insulating layer 17 are next described. First, because the back surface of the conductive pattern 18 approximates the surface of the circuit board 16, heat generated inside the device can be discharged to the exterior via the conductive pattern 18 and the insulating layer 17. In this embodiment, the insulating layer 17 is used which is filled with a filler. To improve heat radiation, it is preferable to use the insulating layer 17 which is thin and at the same time can ensure voltage withstand. With this configuration, the distance between the conductive pattern 18 and the circuit board 16 can be reduced. This reduction of distance plays an important role in improving heat radiation properties of the entire device.

Moreover, with the same configuration, the area where the back surface of the conductive pattern 18 and the insulating layer 17 come in contact can be increased, thus enabling further improvement of heat radiation. If the convex portion is formed to be a cube, four sides thereof except the upper side come in contact with the insulating layer 17. To improve heat radiation, it is also possible to create a configuration lacking heat sinks. Moreover, partially burying the conductive pattern 18 in the insulating layer 17 enables improvement of adhesion between the two elements. Accordingly, peeling strength of the conductive pattern 18 can be improved. The conductive pattern 18 at other regions is not buried in the insulating layer 17 so that the distance with the circuit board 16 can be increased and occurrence of a large parasitic capacitance can be suppressed. Accordingly, even when a high-frequency electrical signal passes through the conductive pattern 18, deterioration of the signal by the parasitic capacitance can be prevented.

In FIG. 4B, the back surface of the convex portion 22 and the front surface of the protrusion 25 are in direct contact so that the conductive pattern 18 mounting the semiconductor element 14A is in contact with the circuit board 16. The convex portion 22 provided on the conductive pattern 18 reduces the size of the protrusion 25 that extends outwardly.

In FIG. 4C, the column-like protrusion 25 is formed so that the upper edge of the protrusion 25 contacts the back surface of the convex portion 22.

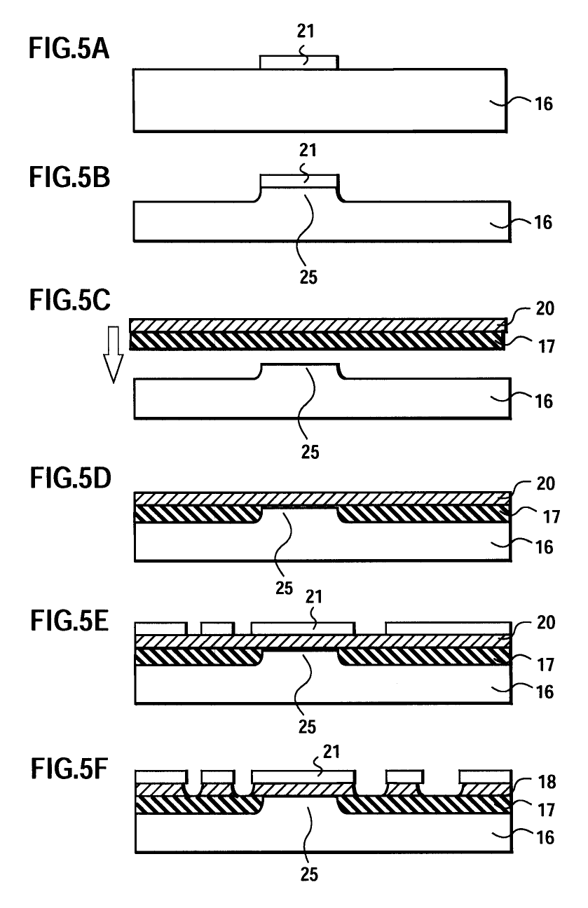

A manufacturing method of the above-described hybrid integrated circuit device is next described with reference to FIG. 5 to FIG. 9. First, a manufacturing method of the conductive pattern 18 having the cross-sectional configuration shown in FIG. 3A or FIG. 3B is described.

The circuit board 16 is prepared and a resist is patterned on a surface thereof as shown in FIG. 5A. Cu, Fe—Ni or Al can be used as a main material for the circuit board 16. In order to assure a mechanical support of the pattern formed on the surface of the circuit board 16, the thickness of the circuit board 16 can be selected to be within the range of 1 to 2 mm. When Cu is used as main material for the circuit board 16, the efficiency of heat radiation can be improved because Cu is a material exhibiting excellent heat conductance. Here, a resist 21 covers the surface of the circuit board at the region where the protrusion 25 is going to be formed.

As shown in FIG. 5B, the circuit board 16 is wet-etched using the resist 21 as an etching mask. During this etching process, the surface of the circuit board 16 at regions which are not covered by the resist 21 is etched. The region covered by the resist 21 extends upwardly to form the protrusion 25. Concretely, the protrusion 25 can extend in a range within several tens μm and several hundreds μm. When this process is over, the resist 21 is removed.

The circuit board 16 and a conductive foil 20 are attached via the insulating layer 17, as shown in FIG. 5C and FIG. 5D. Concretely, the conductive foil 20 is attached to the circuit board 16 so that the protrusion 25 is buried into the insulating layer 17. This process is carried out in a vacuum press so that voids that are generated by the air between the conductive foil 20 and the insulating layer 17 can be prevented. Side surfaces of the protrusion 25 formed by isotropic etching are smooth curved surfaces. Accordingly, when the conductive foil 20 is pressed into the insulating layer 17, resin is injected along this curved surface so that unfilled places are not generated. It is also possible to suppress generation of voids by the curved side surfaces of the convex portion 22. Moreover, burying the protrusion 25 into the insulating layer 17 can improve adhesion strength of the conductive foil 20 and the insulating layer 17.

The conductive pattern 18 is formed by etching via the resist 21 as shown in FIG. 5E and FIG. 5F. When the etching process has finished, the resist 21 is removed.

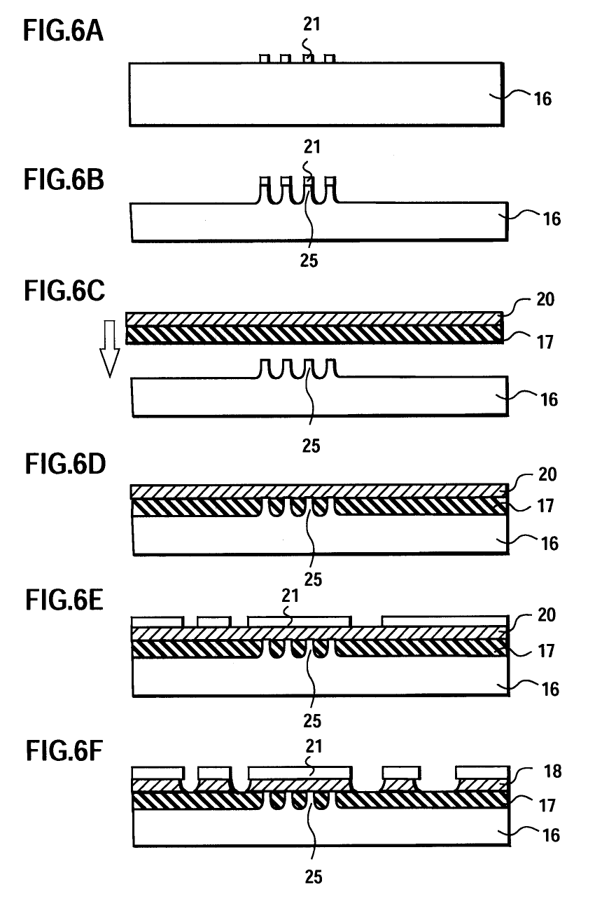

Next, a manufacturing method of the device illustrated in FIG. 3C is described with reference to FIG. 6. Here, the conductive pattern 18 is basically formed in the same manner as the conductive pattern 18 shown in FIG. 5, so that a description is given only of the differences therebetween.

The protrusion 25 is formed by etching after the surface of the circuit board is covered by the resist 21 as illustrated in FIG. 6A and FIG. 6B. Here, a plurality of the column-like protrusions 25 are formed by discretely forming the resists 21 and etching. Side surfaces of the each protrusion 25 formed by etching are curved.

The circuit board 16 and the conductive foil 20 are attached via an insulating layer, as shown in FIG. 6C. In this embodiment, the column-like shape of the protrusion 25 facilitates burying of the protrusion 25 into the insulating layer 17. The area on the surface of the each protrusion 25 is small, making it possible to easily penetrate the insulating layer 17 and contact the upper edge of the each protrusion 25 with the back surface of the conductive foil 20. However, it is also possible to bury the protrusions 25 so that the upper edges of the protrusions 25 do not contact the back surface of the conductive foil 20.

After the resist 21 is coated on the surface of the conductive foil 20, the resist 21 is patterned in order to form the conductive patterns 18 as illustrated in FIG. 6E and FIG. 6F. The conductive patterns 18 are obtained after carrying out an etching process.

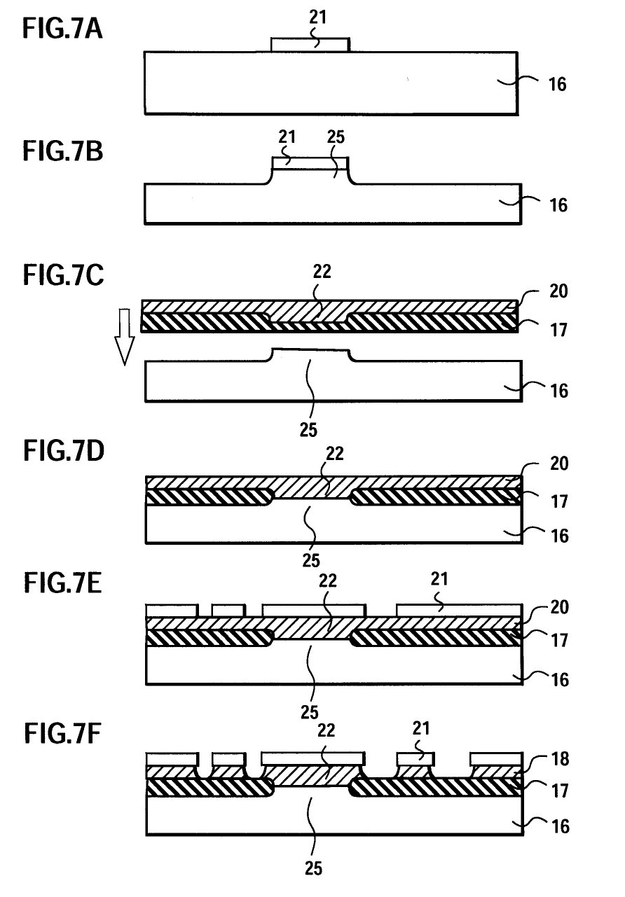

FIG. 7 show a manufacturing method of the hybrid integrated circuit device having the configuration illustrated in FIG. 4.

After the surface of the circuit board 16 is partially covered with the resists 21, the protrusion 25 is formed by etching, as shown in FIG. 7A and FIG. 7B.

The conductive foil 20 and the circuit board 16 are attached via the insulating layer 17, as shown in FIG. 7C and FIG. 7D. The convex portion 22 is formed on the back surface of the conductive foil 20 and the conductive foil 20 is attached to the circuit board 16 so that the convex portion 22 is buried in the insulating layer 17. Here, the location where the convex portion 22 is provided corresponds to the protrusion 25 provided in the circuit board 16. The convex portion 22 of the conductive foil 20 is contacted with the protrusion 25. In this case it is preferable that the length obtained by summing up the protruding volume of the convex portion 22 and the protruding volume of the protrusion 25 be equal to the thickness of the insulating layer 17. Moreover, the lower edge of the convex portion 22 may be separated and insulated from the upper edge of the protrusion 25.

An etching process is carried out after the resist 21 is patterned on the surface of the conductive foil 20 so that predetermined patterns 18 are formed as shown in FIG. 7E and FIG. 7E

Next, processes subsequent to the patterning process are described in detail.

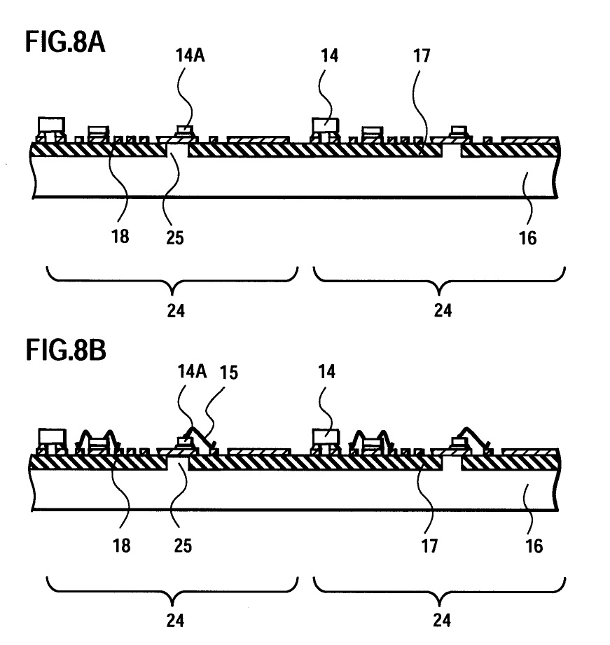

First, the circuit element 14 is secured to the conductive pattern (island) 18 via conductive pastes, etc. such as solder, as shown in FIG. 8A. Here, unit 24 constituting the one hybrid integrated circuit device is formed to be one circuit board 16 so that lump die-bonding and wire-bonding can be carried out. Here, active elements are mounted face-down, but they may also be mounted face-down, as required. A semiconductor element 14A generating heat is secured to the conductive pattern 18 having the protrusion 25 formed at a lower side thereof. In case the back surface of the semiconductor element 14 is connected to the exterior, the semiconductor element 14A can be secured via conductive adhesives. In case the back surface of the semiconductor element 14A is not connected to the exterior, the semiconductor element 14A can be secured via insulating adhesives.

In FIG. 8B, the circuit element 14 and the conductive pattern 18 are electrically connected via fine metal wires 15.

After the above process has been completed, the individual units 24 are separated. The each unit can be separated by stamping using a press, by dicing, by meandering etc. Next, the leads 11 are secured to the circuit boards 16 of each individual unit.

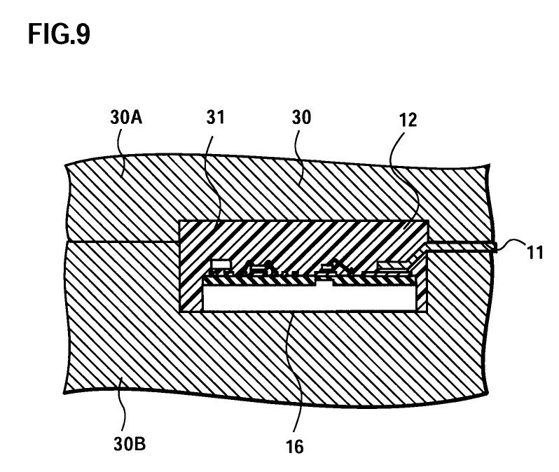

Next, resin sealing of the each circuit board 16 is carried out as shown in FIG. 9. Here, sealing is carried out by transfer mold using a thermosetting resin. After the circuit board 16 is housed in a mold 30 comprising an upper mold 30A and a lower mold 30B, the leads 11 are fixed by engaging the molds. Resin is injected inside a cavity 31 in a process of resin sealing. The hybrid integrated circuit device shown in FIG. 1 is manufactured according to the processes described hereinbefore.

What is claimed is:

1. A circuit device comprising:
a circuit board,
an insulating layer formed on the circuit board,
a conductive pattern formed on the insulating layer,
a circuit element electrically connected to the conductive pattern,
wherein a protrusion partially extending and being buried in the insulating layer is provided on the circuit board.

2. The circuit device of claim 1, wherein the protrusion and the conductive pattern are put in direct contact.

3. The circuit device of claim 1, wherein the insulating layer is provided between the protrusion and the conductive pattern.

4. The circuit device of claim 1, wherein the protrusion is provided on the circuit board at a location corresponding to a lower part of the conductive pattern having the circuit element disposed thereon.

5. The circuit device of claim 1, wherein the circuit board is formed of a metal mainly comprising copper.

6. The circuit device of claim 1, wherein the protrusion has a column-like shape.

7. The circuit device of claim 1, wherein
a semiconductor element having no terminals on a back surface thereof is employed as the circuit element;
the protrusion is provided on the circuit board at a location corresponding to a lower part of the conductive pattern having the semiconductor element attached thereto;
the conductive pattern having the semiconductor element attached thereto and the protrusion are in direct contact.

8. The circuit device of claim 1, wherein
a convex portion is formed in a rear surface of the conductive pattern located above the protrusion and the convex portion is buried in the insulating layer.

9. A method of manufacturing a circuit device forming an electrical circuitry comprising a conductive pattern and a circuit element provided on a circuit board via an insulating layer, including
providing a protrusion extending partially on the circuit board;
burying the protrusion into the insulating layer.

10. A manufacturing method of a circuit device comprising:
providing a protrusion extending partially on a circuit board;
attaching a conductive foil on the circuit board via an insulating layer covering the circuit board so as to bury the protrusion;
forming a conductive pattern by patterning the conductive foil;
electrically connecting the conductive pattern with a circuit element.

11. The method of claim 8 or claim 9, wherein the protrusion is formed by etching.

12. The method of claim 8 or claim 9, wherein the protrusion has a column-like shape.

13. The method of claim 8 or claim 9, wherein an upper surface of the protrusion is formed to be planar and an insulating layer is interposed between the protrusion and the conductive pattern.

14. The method of claim 8 or claim 9, wherein sidewalls of the protrusion are formed to have a curved surface.
